(19) United States
(12) Patent Application Publication
(10) Pub. No.: US 2026/0052675 A1
(43) Pub. Date: Feb. 19, 2026

(54) SEMICONDUCTOR DEVICE AND METHOD OF FORMING THE SAME

(71) Applicant: NANYA TECHNOLOGY CORPORATION, New Taipei City (TW)

(72) Inventors: Yao-Hsiung KUNG, New Taipei City (TW); Chen-Hao LIEN, New Taipei City (TW)

(21) Appl. No.: 18/804,407

(22) Filed: Aug. 14, 2024

(51) Int. Cl. H10B 12/00

(52) U.S. Cl. CPC H10B 12/482; H10B 12/033; H10B 12/315

(57) ABSTRACT

A manufacturing method of a semiconductor device includes forming bit line structures over a substrate, forming spacers along sidewalls of the bit line structures, wherein each of the spacers includes an air gap. The method further includes forming conductive structures between and over the bit line structures, wherein the conductive structures expose a portion of the bit line structures. The method further includes forming isolation structures between the conductive structures and the bit line structures, implanting the isolation structures to form implanted isolation structures, forming a supporting layer over the implanted isolation structures and the conductive structures, and forming capacitor structures over the conductive structures and the implanted isolation structures.

### BACKGROUND

### Field of Invention

The present disclosure relates to a semiconductor device and a method of forming the same.

### Description of Related Art

A conventional semiconductor device connects a capacitor and a transistor. For example, the capacitor may perfectly sit on the landing pad. As the technology scaling, the overlay control between the capacitors and landing pads needs more precisely to gain process integration margin. However, the isolation structure adjacent the landing pad may be easily damaged during the formation of the capacitors, causing electrical short and loss of air gap function.

### SUMMARY

The disclosure provides a manufacturing method of a semiconductor device. The method includes forming bit line structures over a substrate, forming spacers along sidewalls of the bit line structures, wherein each of the spacers includes an air gap. The method further includes forming conductive structures between and over the bit line structures, wherein the conductive structures expose a portion of the bit line structures. The method further includes forming isolation structures between the conductive structures and the bit line structures, implanting the isolation structures to form implanted isolation structures, forming a supporting layer over the implanted isolation structures and the conductive structures, and forming capacitor structures over the conductive structures and the implanted isolation structures.

The disclosure provides a semiconductor device. The semiconductor device includes a substrate, bit line structures over the substrate, spacers along sidewalls of the bit line structures, conductive structures between the spacers, and isolation structures between the conductive structures and the bit line structures, wherein each of the spacers includes an air gap and the isolation structures are implanted.

The semiconductor device with implanted isolation structures between the conductor structures and the bit line structures. The implanted isolation structures have higher etching resistance, which may prevent from punching through the air gaps AG when a formation of the capacitor structures is misalignment. Furthermore, a width of bottom surface of bottom electrodes layers may be enlarged, so that improves contact resistance between the capacitor structures and the landing pads.

### BRIEF DESCRIPTION OF THE DRAWINGS

The disclosure can be more fully understood by reading the following detailed description of the embodiment, with reference made to the accompanying drawings as follows:

FIGS. 1-14 are cross-section views of a manufacturing method of forming a semiconductor device at different stages according to some embodiments of the present disclosure.

FIGS. 15-16 are cross-section views of a semiconductor device according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

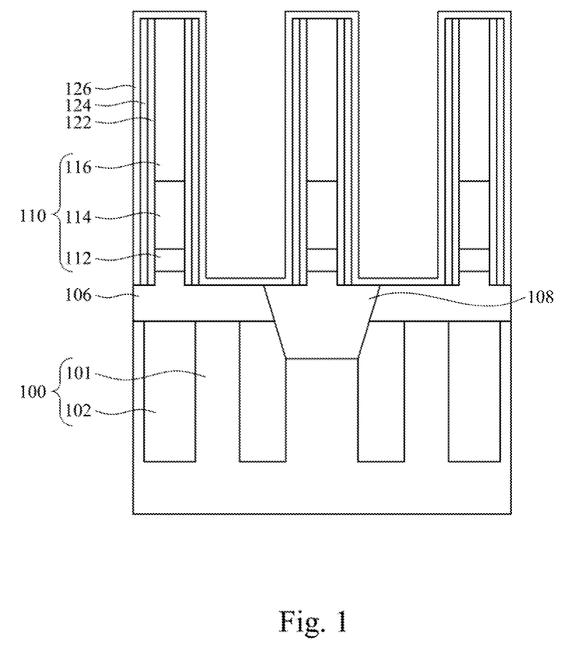

Referring to FIG. 1, a substrate 100 is provided. The substrate 100 includes active regions 101 and isolation structures 102 defining the active regions 101 in the substrate 100. A dielectric layer 106 is formed over the active regions 101 and the isolation structures 102. A bit line contact 108 is formed in the dielectric layer 106 and is in contact with the active regions 101. The substrate 100 may be a silicon substrate or other suitable semiconductor substrate. The isolation structures 102 may be made of silicon oxide, silicon nitride, or the like. The dielectric layer 106 may be made of silicon oxide, silicon nitride, or the like.

Bit line structures 110 are formed over the substrate 100. The bit line structures 110 include a barrier layer 112, a metal layer 114 over the barrier layer 112, and a hard mask layer 116 over the metal layer 114. The bit line structures 110 may be formed by, for example, sequentially forming a barrier material layer, a metal material layer, and a hard mask material layer over the substrate 100. Subsequently, the barrier material layer, the metal material layer, and the hard mask material layer are patterned into the barrier layer 112, the metal layer 114, and the hard mask layer 116, and the bit line structures 110 are formed.

First spacer layers 122, sacrificial spacer layers 124 and a second spacer layer 126 are sequentially formed along the sidewalls of the bit line structures 110. First, a first spacer material layer is formed conformal to the bit line structures 110 and the dielectric layer 106, then an anisotropic process is performed to remove a horizontal portion of the first spacer material layer, and the vertical portion of the first spacer material layer forms the first spacer layers 122 in contact with and lining the sidewalls of the bit line structures 110. Subsequently, a second spacer material layer is formed conformal to the first spacer layers 122, the bit line structures 110 and the dielectric layer 106, then an anisotropic process is performed to remove a horizontal portion of the second spacer material layer, and the vertical portion of the second spacer material layer forms the sacrificial spacer layers 124 in contact with and lining the first spacer layers 122. Subsequently, the second spacer layer 126 is formed conformal to the sacrificial spacer layers 124, the bit line structures 110 and the dielectric layer 106. The first spacer layers 122, the sacrificial spacer layers 124 and the second spacer layer 126 are made of dielectric material, such as silicon oxide, silicon nitride, or the like, and the sacrificial spacer layers 124 are made of different material from the first spacer layers 122 and the second spacer layers 126. For example, if the first spacer layers 122 and the second spacer layer 126 are made of silicon nitride, the sacrificial spacer layers 124 are made of silicon oxide.

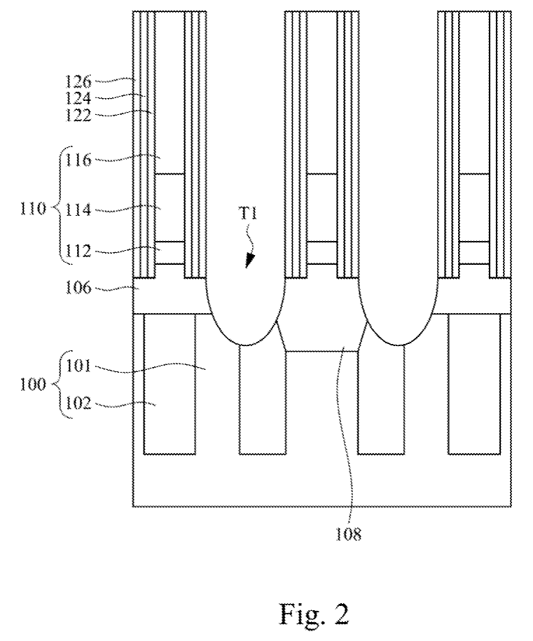

Referring to FIG. 2, trenches T1 are formed between the bit line structures 110 and exposing portions of the substrate 100. Specifically, the trenches T1 are formed by performing an etching process to penetrating through the second spacer layer 126 and the dielectric layer 106 to expose the substrate 100. During forming the trenches T1, the second spacer layer 126 over the bit line structures 110 are also removed, so the top surfaces of the bit line structures 110 are exposed.

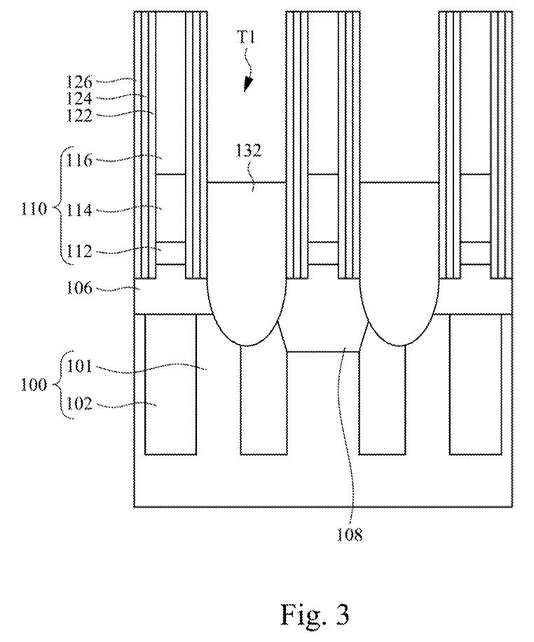

Referring to FIG. 3, first conductive layers 132 are formed in the trenches T1 between the bit line structures 110. Specifically, a first conductive material layer may be firstly formed overfilling in the trenches T1. Subsequently, a planarization process is performed to remove an excess portion of the first conductive material layer over the bit line structures 110 to expose the top surfaces of the bit line structures 110. Subsequently, the first conductive material layer is etched back to form the first conductive layers 132 in the trenches T1. In some embodiments, the first conductive layer 132 is made of doped polysilicon.

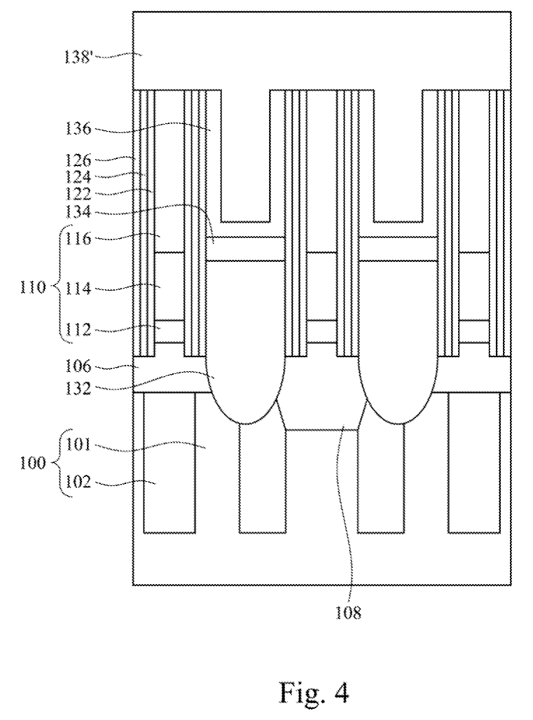

Referring to FIG. 4, second conductive layers 134 are formed over the first conductive layers 132, barrier layers 136 are formed over the second conductive layers 134, and a landing pad material layer 138’ is formed overfilling the trench T1 between the bit line structures 110. In some embodiments, the second conductive layers 134 may be formed by depositing a metal layer in contact with the top surfaces of the first conductive layers 132. In some other embodiments, the second conductive layers 134 may be formed by forming a second conductive material layer overfilling the trenches T1. Subsequently, a planarization process is performed to remove an excess portion of the second conductive material layer over the bit line structures 110 to expose the top surfaces of the bit line structures 110. Subsequently, the second conductive material layer is etched back to form the second conductive layers 134 in the trenches T1 and over the first conductive layers 132.

After forming the second conductive layers 134, the barrier layers 136 are formed over the second conductive layers 134. Specifically, a barrier material layer is formed conformal to the bit line structures 110 and the second conductive layers 134. Subsequently, the barrier material layer over the bit line structures 110 is removed to expose the top surfaces of the bit line structures 110, and the remaining portion of the barrier material layer forms the barrier layers 136. After forming the barrier layers 136, the landing pad material layer 138’ is formed overfilling in the trench T1 between the bit line structures 110. In some embodiments, the second conductive layer 134 is made of metal silicide, the barrier layer 136 is made of TaN, TiN, but not limited thereto, and the landing pad material layer 138’ is made of Ti, TiN, Ta, TaN, W, Cu, Au, or alloys thereof, but not limited thereto.

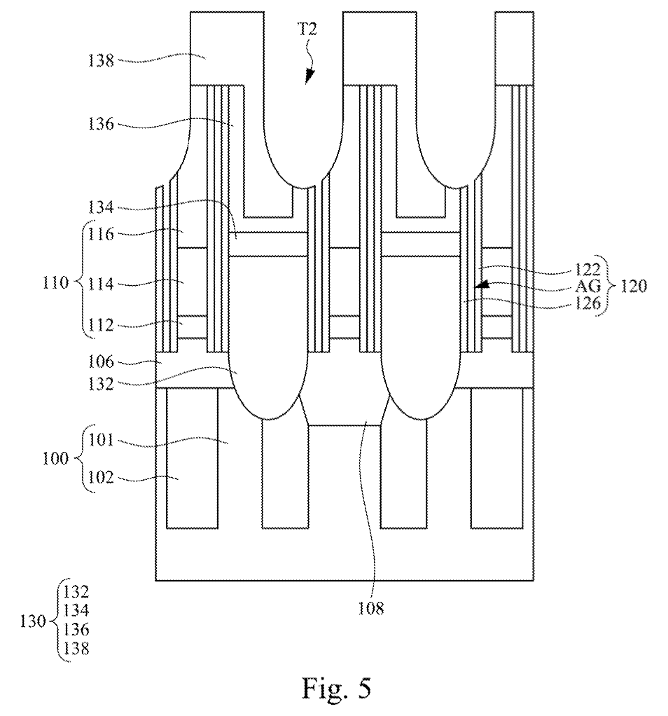

Referring to FIG. 5, trenches T2 are formed by removing a portion of the barrier layer 136, a portion of the landing pad material layer 138’ and a portion of the bit line structures 110. After forming the trenches T2, a remaining portion of the landing pad material layer 138’ over the barrier layers 136 and the bit line structures 110 forms landing pads 138. A first conductive layer 132, a second conductive layer 134, a barrier layer 136, and a landing pad 138 stacked vertically may be collectively referred to as a conductive structure 130. That is, after forming the trenches T2, the conductive structures 130 between and over the bit line structures 110 are formed, and the conductive structures 130 may serve as contacts connecting the active regions in the substrate 100 and the capacitor structures formed subsequently. The trenches T2 may be formed by performing an etching process to expose the sacrificial spacer layers 124 (as shown in FIG. 4), and then the sacrificial spacer layers 124 are removed to form air gaps AG between the first spacer layers 122 and the second spacer layers 126. Therefore, spacers 120 including the first spacer layers 122, the second spacer layers 126 and the air gaps AG are formed along sidewalls of the bit line structures 110. The first spacer layers 122 are in contact with the bit line structures 110. The second spacer layers 126 are in contact with the conductive structures 130, and the first spacer layers 122 are separated from the second spacer layers 126 by the air gaps AG. In some embodiments, the sacrificial spacer layers 124 may be removed by performing a wet etching process.

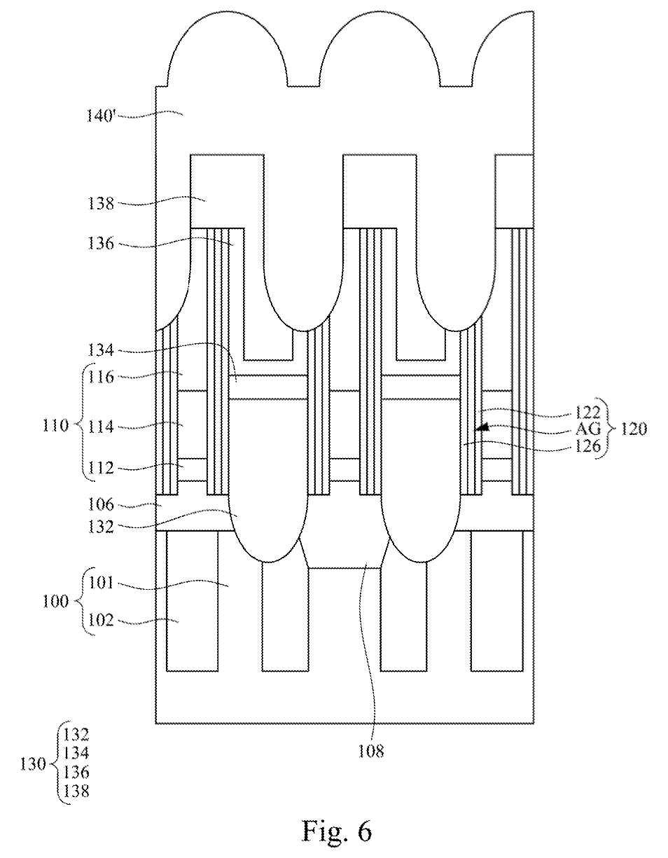

Referring to FIG. 6, an isolation layer 140’ is formed overfilling the trenches T2. The isolation layer 140’ is used to seals the air gaps AG. The manufacturing process and the material of the isolation layer 140’ are selected to allow the isolation layer 140’ seals the air gaps AG but not flow into the air gaps AG. In some embodiments, the isolation layer 140’ is made of any suitable dielectric material, such as silicon, silicon nitride, and the like.

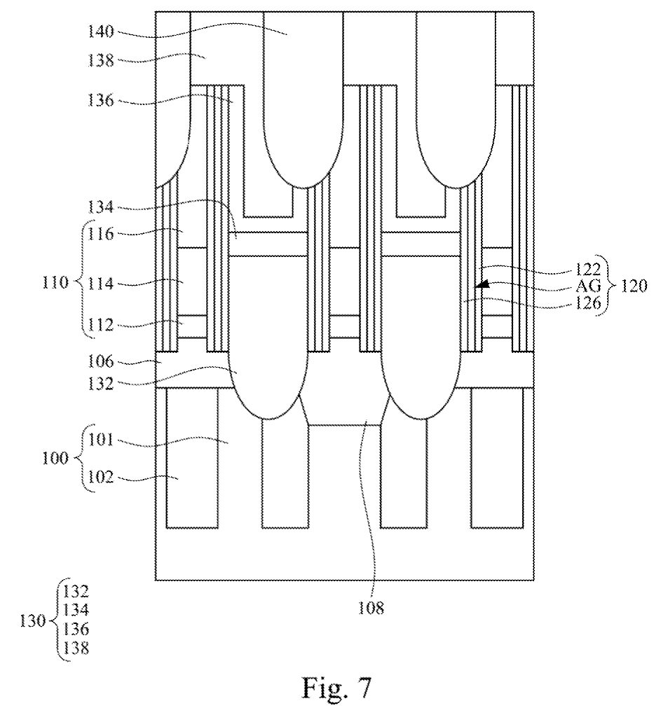

Referring to FIG. 7, a planarization process is performed to remove an top portion of the isolation layer 140’ over the landing pads 138 until top surfaces of the landing pads 138 are exposed. As such, isolation structures 140 are formed between the bit line structures 110 and the conductive structures 130. In some embodiments, top surfaces of the isolation structures 140 are coplanar with the top surfaces of the landing pads 138.

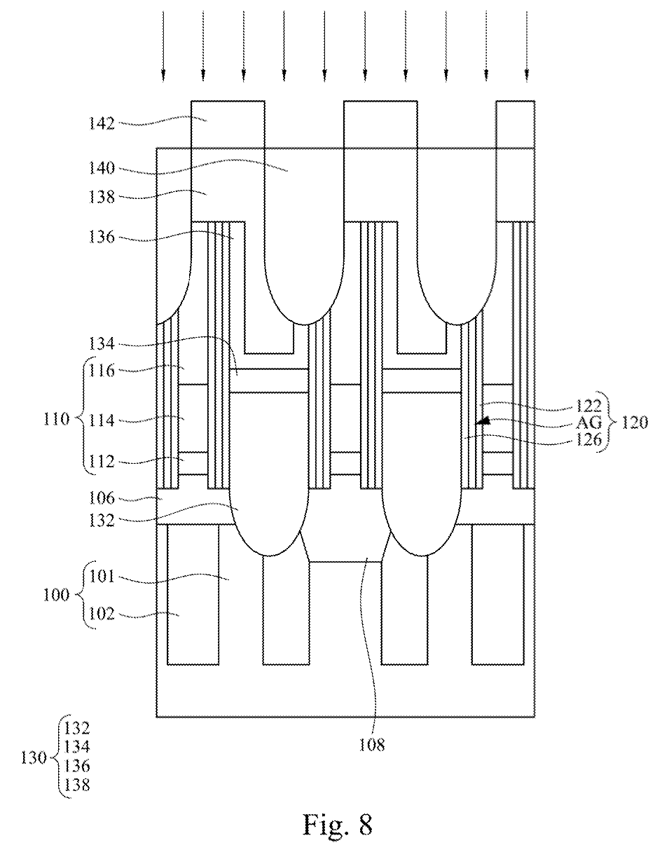

Referring to FIG. 8, a photoresist 142 is formed over the conductive structures 130. The photoresist 142 may be formed by depositing a photoresist layer over the conductive structure 130 and the isolation structures 140, then patterning the photoresist layer to expose the isolation structures 140. After the photoresist 142 is formed, an implanted process is performed to the exposed isolation structures 140. The photoresist 142 may be served as a hard mask layer during the implanted process and prevent the conductive structures 130 from being implanted. In some embodiments, dopants may be selected such as B or Si in the implanted process, and provide a specific property like obviously reduction of dry etching rate. According to the implanted study on nitride film material, using Si with dosage over 3.00E+16 (ion/cm²) under the energy 10 KeV, the dry etching rate of the material may decrease to about 0.26 times than the material without being implanted. When the material are implanted using B with dosage over 5.00E+16 (ion/cm²) under the energy 10 KeV, the dry etching rate of the material may decrease to about 0.75 times than material without being implanted. The dry etching rate is measured by using the etchant gas including C₄F₆, CH₂F₂, C₄F₈ , and O₂ in 30 sec. After the implanted process is performed, a doping depth of the dopants may be distributed about 50 nm from a top surface of the implanted isolation structures 144 by the subsequently thermal process (not shown).

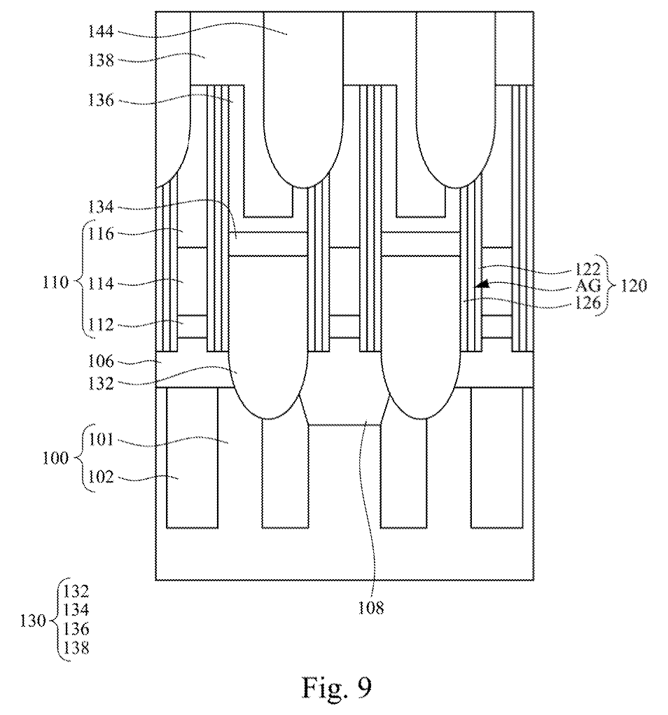

Referring to FIG. 9, implanted isolation structures 144 are formed by the implanted process, followed by removing the photoresist 142. After the isolation structures 140 are implanted, the dry etching rate of the implanted isolation structures 144 may be lower than the isolation structures 140 without being implanted. Based on the selection of the dopants, such as B, Si, during the implanted process, the dry etching rate of the implanted isolation structures 144 may decrease about 0.26 times to about 0.75 times. The implanted isolation structures 144 with such a lower dry etching rate may be served as an etching stop layer and prevent from punching through the air gaps AG in the subsequent process.

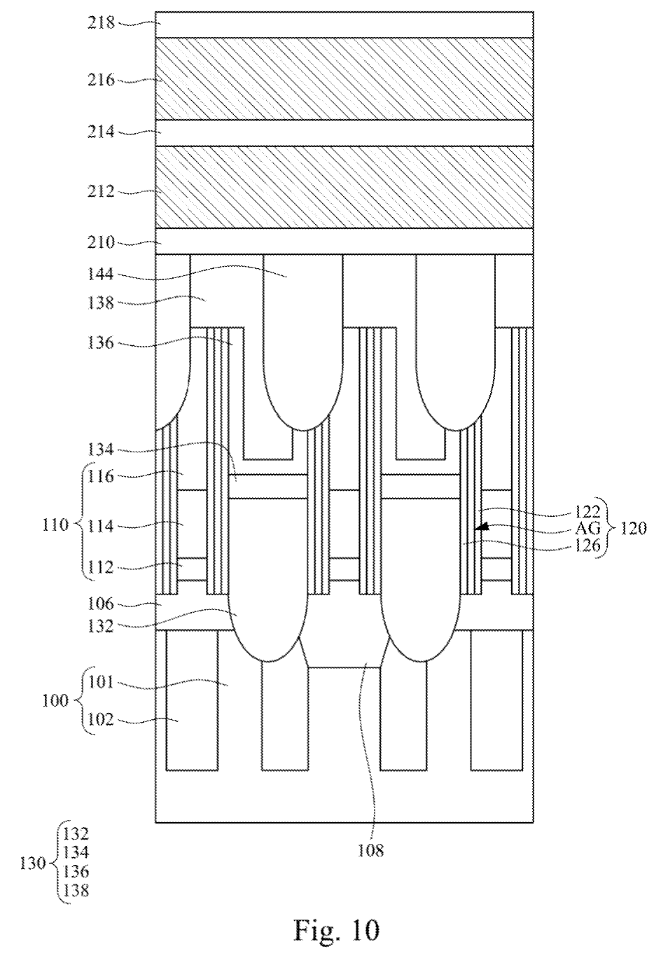

Referring to FIG. 10, a first supporting layer 210, a first sacrificial layer 212, a second supporting layer 214, a second sacrificial layer 216 and a third supporting layer 218 are sequentially formed over the conductive structures 130 and the implanted isolation structure 144. In some embodiments, the first supporting layer 210, the second supporting layer 214 and the third supporting layer 218 are made of dielectric materials, such as silicon nitride. The first sacrificial layer 212 and the second sacrificial layer 216 are made of dielectric materials different from the first supporting layer 210, the second supporting layer 214 and the third supporting layer 218. The first sacrificial layer 212 and the second sacrificial layer 216 may be made of silicon oxide.

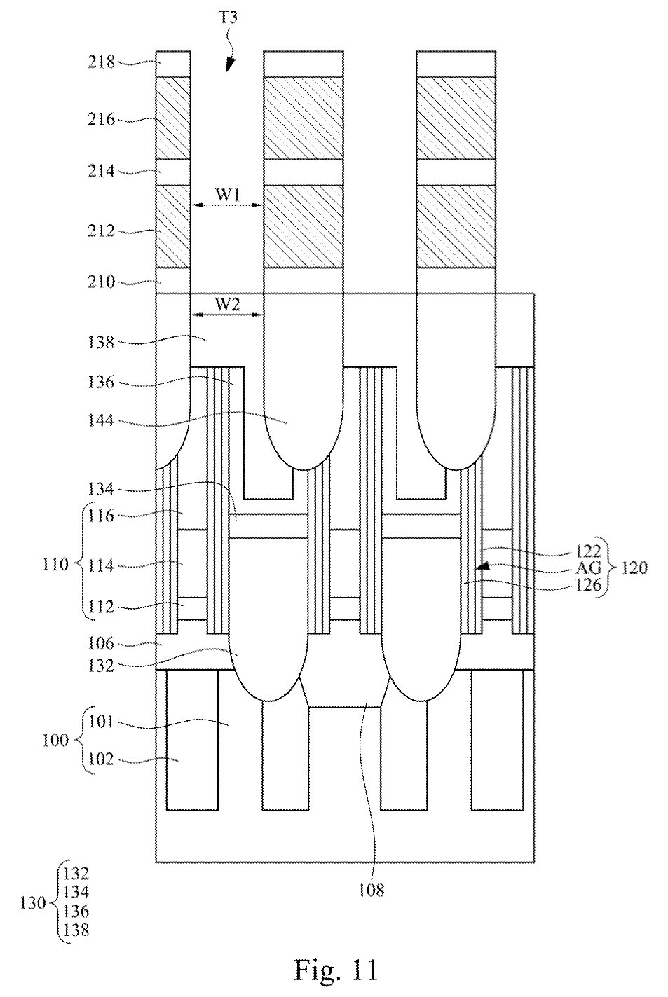

Referring to FIG. 11, trenches T3 penetrating the first supporting layer 210, the first sacrificial layer 212, the second supporting layer 214, the second sacrificial layer 216 and the third supporting layer 218 are formed and expose the conductive structures 130. In some embodiments, the trenches T3 may be formed by performing one or more etching processes. During forming the trenches T3, the implanted isolation structures 144 are used to prevent the process from punching through the air gaps AG. Specifically, at the ideal situation, the trenches T3 completely overlap the top surfaces of the conductive structures 130, and do not expose the implanted isolation structures 144. Therefore, the bottom electrode layers are formed in trenches T3 in the subsequent process and have maximum contact area with the conductive structures 130. However, in some embodiments, the trenches T3 may be misaligned with the top surfaces of the conductive structures 130, and thus the trenches T3 may expose a portion of the implanted isolation structures 144. The implanted isolation structures 144 have a higher etching resistance to an etchant used during forming the trenches T3 than the first supporting layer 210 does. In some embodiments, the first supporting layer 210 may have higher dry etching rate over 8.87 times than the implanted isolation structures 144 such that the implanted isolation structures 144 may serve as an etching stop layer during the formation of the trenches T3. Therefore, even if the implanted isolation structures 144 are exposed during forming the trenches T3, implanted isolation structures 144 may prevent the process in FIG. 11 from the exposure of the air gaps AG. The bottom electrode layer 220 may fill the air gaps AG and cause electrical short between the capacitor structures formed subsequently and the bit line structures 110.

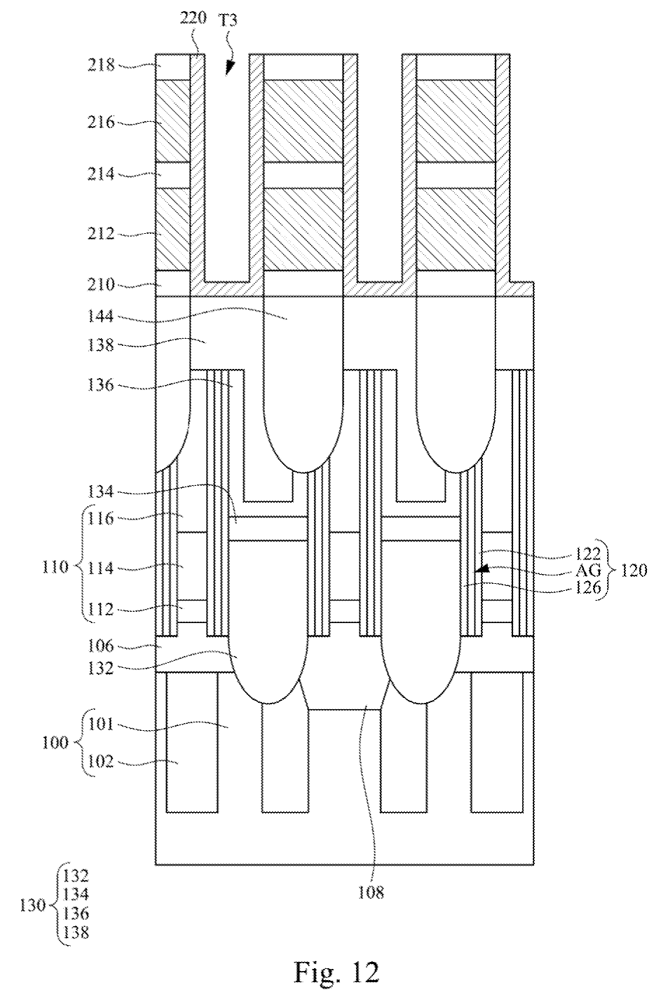

Referring to FIG. 12, bottom electrode layers 220 lining the trenches T3 are formed. In some embodiments, a bottom electrode material layer is first formed lining the trenches T3 and over the third supporting layer 218. Subsequently, the bottom electrode material layer over the third supporting layer 218 is removed by performing, for example, a planarization process. The remaining portion of the bottom electrode material layer forms the bottom electrode layers 220 lining the trenches T3. In some embodiments, the bottom electrode layers 220 may be made of metals, metal compounds, alloy compounds, other conductive materials or combinations thereof, such as titanium nitride or silicon-doped titanium nitride.

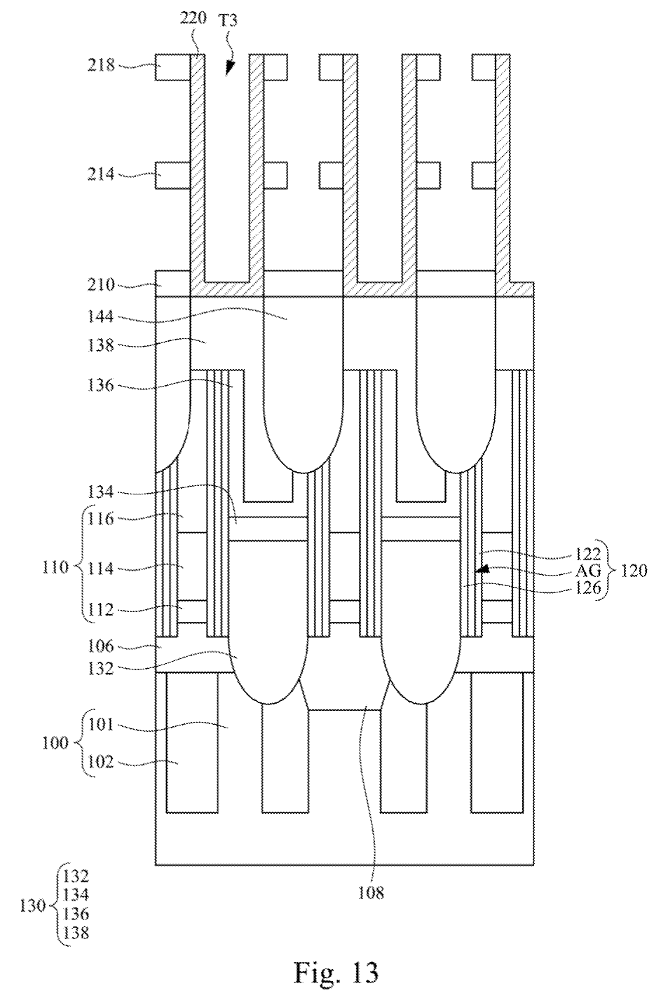

Referring to FIG. 13, the first sacrificial layer 212 and the second sacrificial layer 216 are removed. Specifically, removing the first sacrificial layer 212 and the second sacrificial layer 216 includes forming a hole in some of the third supporting layer 218 until the top surface of the second sacrificial layer 216 is exposed. Subsequently, the second sacrificial layer 216 is removed through the hole by performing a wet etching process. After the second sacrificial layer 216 is removed, a hole in some of the second supporting layer 214 is formed until the top surface of the first sacrificial layer 212 is exposed, and then the first sacrificial layer 212 is removed through the hole by performing a wet etching process. As such, the first supporting layer 210, the second supporting layer 214, the third supporting layer 218 and the bottom electrode layers 220 are still in place.

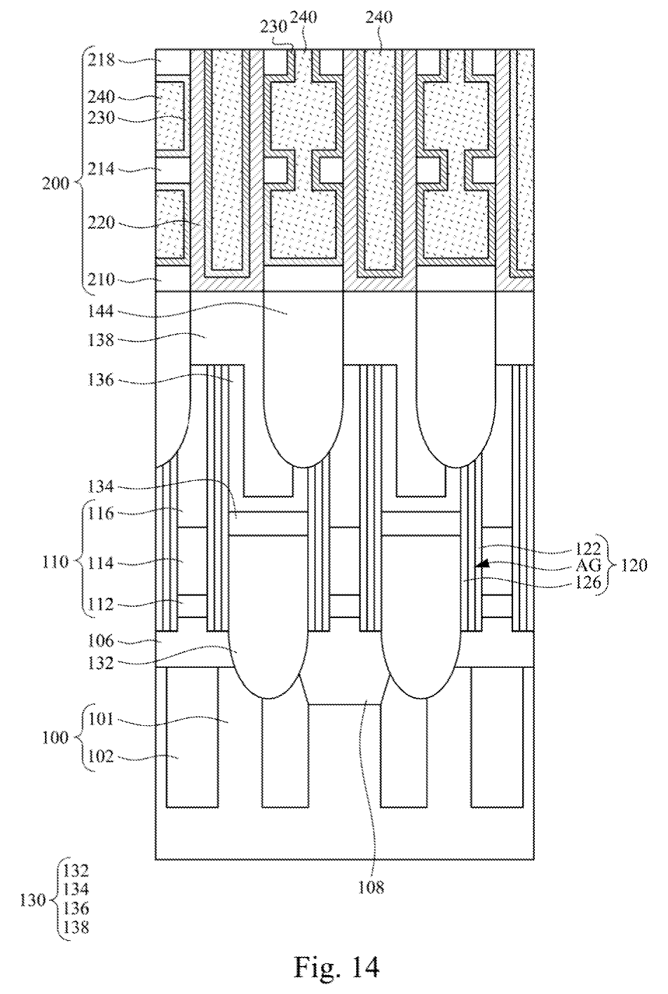

Referring to FIG. 14, dielectric layers 230 lining the bottom electrode layers 220, the first supporting layer 210, the second supporting layer 214 and the third supporting layer 218 are formed, and the top electrode layers 240 are formed between the dielectric layers 230. In some embodiments, the dielectric layers 230 may be made of high-k dielectric material, such as ZrO₂, and the top electrode layers 240 may be made of metals, metal compounds, alloy compounds, other conductive materials or combinations thereof, such as titanium nitride or silicon-doped titanium nitride. As such, a capacitor structure 200 is formed over the conductive structures 130 and the isolation structures 140. The bottom electrode layers 220 of the capacitor structure 200 are in contact with the conductive structures 130. The dielectric layer 230 is lining the bottom electrode layers 220, and the top electrode layer 240 is lining the dielectric layer 230.

The resulting semiconductor device is shown in FIG. 14. The resulting semiconductor device includes the substrate 100, the bit line structures 110, the spacers 120, the conductive structures 130, the implanted isolation structures 144 and the capacitor structure 200. The bit line structures 110 are over the substrate 100. The spacers 120 are along the sidewalls of the bit line structures 110, and each of the spacers 120 includes an air gap AG. The conductive structures 130 are between the spacers 120. The implanted isolation structures 144 are between the conductive structures 130 and the bit line structures 110. The capacitor structure 200 includes the first supporting layer 210 over the implanted isolation structures 144, the bottom electrode layers 220 over the conductive structures 130, the dielectric layer 230 lining the bottom electrode layers 220, the second supporting layer 214 and the third supporting layer 218 and the top electrode layer 240 lining the dielectric layer 230.

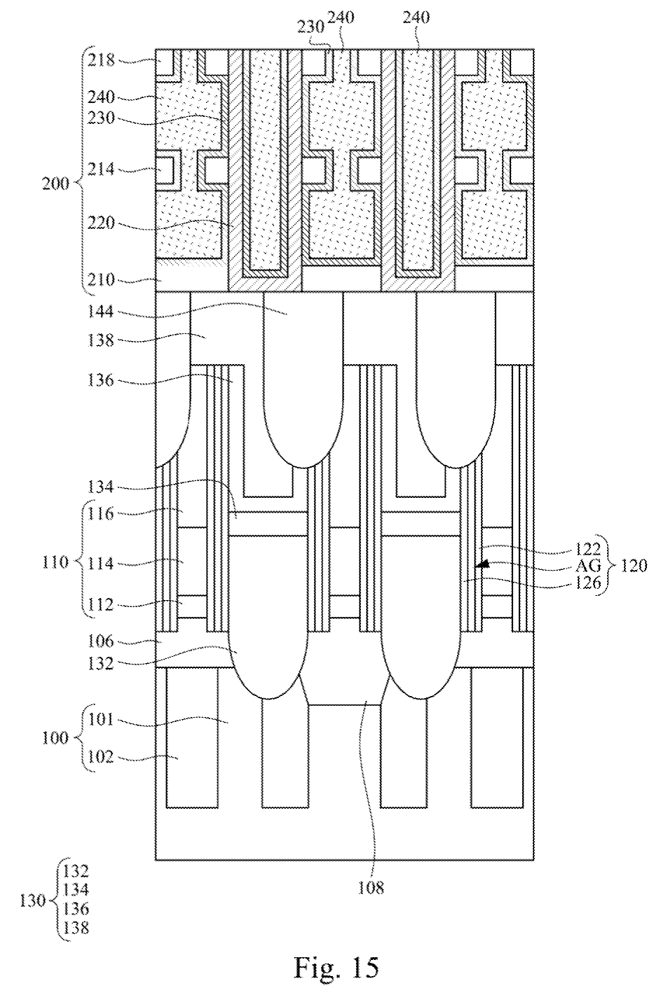

Each of the implanted isolation structures 144 seals the air gap AG, and the implanted isolation structures 144 are in contact with the bit line structures 110 and the conductive structures 130. The implanted isolation structures 144 performed by using Si, B as a dopant under specific dosages may have lower dry etching rate than the isolation structures 140 without being implanted. Further, a ratio of the dry etching rate between the first supporting layer 210 and the implanted isolation structures 144 is about 8.87. The implanted isolation structures 144 is also used to prevent the process of manufacturing the capacitor structure 200 from exposing the air gap by punching if the capacitor structure 200 shifts from the top surface of the conductive structures 130, as shown in FIG. 15.

In FIG. 15, the trenches for forming the bottom electrode layer 220 (such as trenches T3 in FIG. 11) shift from the top surfaces of the conductive structures 130 due to misalignment. As mentioned before, the implanted isolation structures 144 are performed implanted process to have higher etching resistance to the etchant used for forming the trenches for forming the bottom electrode layer 220. Therefore, the implanted isolation structures 144 serves as the etching stop layer, and the air gaps AG below are still sealed after forming the capacitor structure 200. The resulting bottom electrode layers 220 also shift from the top surface of the conductive structures 130 and are in contact with the implanted isolation structures 144. If the implanted isolation structures 144 having higher etching resistance to the etchant mentioned in FIG. 11 is not presented, the air gaps AG are opened up if the trenches for forming the bottom electrode layer 220 (such as trenches T3 in FIG. 11) shift from the top surfaces of the conductive structures 130. The bottom electrode layer 220 may fill the air gaps AG and cause electrical short between the capacitor structure 200 and the bit line structures 110.

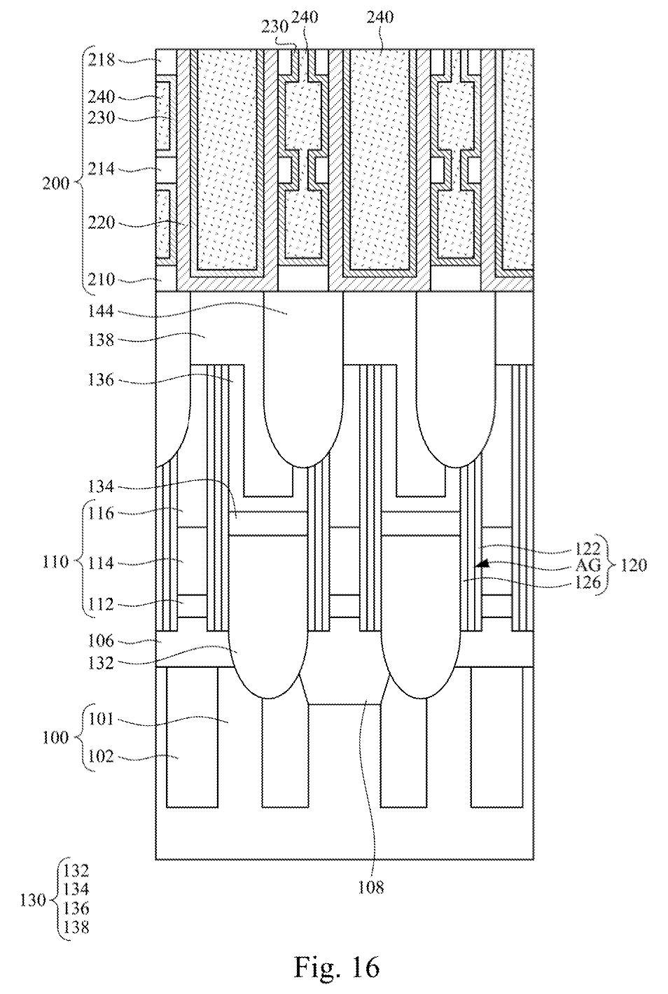

FIG. 16 illustrates another embodiment of the semiconductor device of the present disclosure. The trenches T3 may be formed to have a width W1 larger than a width W2 of a top surface of the conductive structures 130 due to higher etching resistance of the implanted isolation structures 144 (as shown in FIG. 11). The trench T3 may expose the top surface of portions of the implanted isolation structures 144 and the conductive structures 130. After the formation of the bottom electrode layers 220, a width of a bottom surface of the bottom electrode layers 220 is larger than the width W2 of the top surface of the conductive structures 130, resulting in larger contact area between the bottom electrode layers 220 and the conductive structures 130. The larger contact area between the bottom electrode layers 220 and the conductive structures 130 may induce a benefit of lower contact resistance.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this invention provided they fall within the scope of the following claims.

What is claimed is:

1. A manufacturing method of a semiconductor device, comprising:
forming a plurality of bit line structures over a substrate;
forming a plurality of spacers each comprising an air gap along sidewalls of the bit line structures;
forming a plurality of conductive structures between and over the bit line structures, wherein the conductive structures expose a portion of the bit line structures;
forming a plurality of isolation structures between the conductive structures and the bit line structures;
implanting the isolation structures to form a plurality of implanted isolation structures;
forming a supporting layer over the implanted isolation structures and the conductive structures; and
forming a plurality of capacitor structures over the conductive structures and the implanted isolation structures.

2. The method of claim 1, wherein forming the plurality of spacers each comprising an air gap along sidewalls of the bit line structures:
sequentially forming a first spacer layer, a sacrificial spacer layer and a second spacer layer along the sidewalls of the bit line structures; and
removing the sacrificial spacer layer after forming the conductive structures.

3. The manufacturing method of claim 1, wherein forming the plurality of the conductive structures between and over the bit line structures comprises:
forming a first trench between the bit line structures and exposing portions of the substrate;
forming a first conductive layer in the first trench;
forming a second conductive layer over the first conductive layer;
forming a barrier layer over the second conductive layer;
forming a landing pad overfilling the first trench; and
forming a second trench by removing a portion of the barrier layer, a portion of the landing pad and a portion of the bit line structures.

4. The manufacturing method of claim 1, wherein forming the plurality of the isolation structures between the conductive structures and the bit line structures comprises:
forming an isolation layer between and over the conductive structures and the bit line structures, and
removing a top portion of the isolation layer, wherein a top surface of the isolation layer is coplanar with a top surface of the conductive structures.

5. The manufacturing method of claim 1, wherein implanting the isolation structures to form a plurality of implanted isolation structures comprises:
forming a photoresist over the conductive structures, and
implanting dopants into the isolation structures.

6. The manufacturing method of claim 5, wherein a doping depth of the dopants is about 50 nm from a top surface of the implanted isolation structures.

7. The manufacturing method of claim 1, wherein the implanted isolation structures has a first dry etching rate lower than a second dry etching rate of the isolation structures.

8. The manufacturing method of claim 1, wherein the implanted isolation structures has a first dry etching rate lower than a third dry etching rate of the supporting layer.

9. The manufacturing method of claim 8, wherein a ratio of the third dry etching rate and the first dry etching rate is above 8.87.

10. The manufacturing method of claim 1, wherein forming a plurality of capacitor structures over the conductive structures and the implanted isolation structures comprising:
forming a plurality of bottom electrodes over the conductive structures;
forming a plurality of dielectric layers lining the bottom electrode; and
forming a plurality of top electrode layers lining the dielectric layer.

11. A semiconductor device, comprising:
a substrate;
a plurality of bit line structures over the substrate,
a plurality of spacers along sidewalls of the bit line structures, wherein each of the spacers comprises an air gap;
a plurality of conductive structures between the spacers; and
a plurality of implanted isolation structures between the conductive structures and the bit line structures.

12. The semiconductor device of claim 11, wherein each of the spacers comprises:
a first spacer layer in contact with one of the bit line structures; and
a second spacer layer in contact with one of the conductive structures, wherein the first spacer layer is separated from the second spacer layer by the air gap.

13. The semiconductor device of claim 11, further comprising:
a plurality of capacitor structures over the conductive structures and the implanted isolation structures, wherein each of the capacitor structures comprise:
a bottom electrode in contact with the conductive structure;
a dielectric layer lining the bottom electrode; and
a top electrode layer lining the dielectric layer.

14. The semiconductor device of claim 13, wherein the bottom electrodes of the capacitor structures are further in contact with the implanted isolation structures.

15. The semiconductor device of claim 13, wherein a width of a bottom surface of the bottom electrodes is larger than a width of a top surface of the conductive structures.

16. The semiconductor device of claim 11, wherein a top surface of the implanted isolation structures is coplanar with a top surface of the conductive structures.

17. The semiconductor device of claim 11, wherein the implanted isolation structures are implanted by B, Si as dopants.

18. The semiconductor device of claim 17, wherein a doping depth of the dopants is 50 nm from a top surface of the implanted isolation structures.

19. The semiconductor device of claim 11, wherein the implanted isolation structures are in contact with the spacers and the bit line structures.
